(19) United States
(12) Patent Application Publication
(10) Pub. No.: US 2006/0147834 A1
(43) Pub. Date: Jul. 6, 2006

(54) Water-soluble composition for coating photoresist pattern and method for forming fine patterns using the same

(75) Inventors: Geun Su Lee, Gyeonggi-Do (KR); Seung Chan Moon, Gyeonggi-do (KR); Seung Hun Lee, Daegugwangyeok-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignees: HYNIX SEMICONDUCTOR INC., Gyeonggi-do (KR); Youngchang Chemical Co., Ltd., Daegugwangyeok-si (KR)

(21) Appl. No.: 11/121,769

(22) Filed: May 4, 2005

(30) Foreign Application Priority Data
Dec. 30, 2004 (KR) 10-2004-0117172

(51) Int. Cl. G03F 7/004

(52) U.S. Cl. 430/270.1; 430/322

(57) ABSTRACT

A composition for coating a photoresist pattern which comprises water and a compound of Formula 1 is coated on a previously formed photoresist pattern, thereby reducing a size of a space or contact hole of photoresist pattern effectively. The method using the composition is applied to all semiconductor processes for forming a fine photoresist pattern.

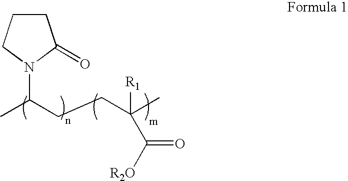

wherein R₁ and R₂ are individually selected from the group consisting of H, linear or branched C₁-C₂₀ alkyl, linear or branched C₂-C₂₀ alkyl containing an ester linkage, linear or branched C₂-C₂₀ alkyl containing a ketone linkage, linear or branched C₂-C₂₀ alkyl containing a carboxylic acid group, linear or branched C₇-C₂₀ alkyl phenyl and linear or branched C₃-C₂₀ alkyl containing a acetal linkage; m is an integer ranging from 0 to 3000; and n is an integer ranging from 10 to 3000.

### BACKGROUND OF THE DISCLOSURE

1. Technical Field

This disclosure relates to a composition for coating a photoresist pattern and a method for forming a fine pattern using the same. A disclosed method for forming a fine pattern includes coating a composition for coating a photoresist pattern which comprises water and a compound of Formula 1 on a previously formed photoresist pattern to reduce a size of a space or contact hole of photoresist pattern, thereby obtaining a fine photoresist pattern.

2. Description of the Related Art

As the manufacturing technology of semiconductor devices has developed and the application field of memory devices has been extended, a reduction of the design rule has been accelerated by improvements in lithography processes. That is, development of photoresist materials, new exposure sources and related equipment have taken place to develop a memory device having improved integrity.

However, since the resolution obtained by using currently available KrF and ArF lasers is limited within 0.1 μm, it is difficult to form a fine pattern for an integrated semiconductor device.

A resist flow process (hereinafter, referred to as “RFP”) is a representative method for forming a conventional fine pattern.

As shown in FIG. 1, according to the above-described RFP, a photoresist pattern 5 is formed on a substrate 1 with an underlying layer 3 by performing an exposure process and a developing process. Then, thermal energy 7 is applied to the resulting structure at over a glass transition temperature of photoresist for a predetermined time, which results in an inward thermal flow 9 of the photoresist to reduce a size of a space or contact hole of photoresist pattern

Although the RFP is a simple method, the contraction degree of the pattern depends on the amount of the photoresist. In other words, the pattern is contracted largely if the amount of the photoresist which can be flown in an upper layer portion, a middle layer portion and lower layer portion is large, and contracted slightly if the amount of the photoresist is small. As a result, a uniform pattern cannot be formed because the contraction degree of the pattern is differentiated when the RFP is performed on a pattern not having a uniform amount of photoresist.

In addition, even when the same thermal energy is transmitted on the entire surface of photoresist during RFP in excess of the glass transition temperature of the photoresist, the photoresist flow from the upper portion and the lower portion more rapidly than from the middle portion. As a result, the profile of the pattern can be bent or collapsed (i.e., non-vertical walls). Moreover, the pattern may be at least partially filled due to an over flowing during RFP.

The above phenomena such as deflection, collapse and filling of the pattern is exacerbated when the temperature is not controlled and the flowing time becomes longer than a predetermined period since most of the photoresist is sensitive to the applied heat.

In order to solve the above-described problems, a method using resist enhancement lithography assisted by chemical shrink (hereinafter, referred to as “RELACS”) material produced by Clariant Co. or an applying of a shrink assist film for enhanced resolution (hereinafter, referred to as “SAFIER”) material produced by TOK Co. has been developed.

According to the method using the RELACS material, as shown in FIG. 2, a photoresist pattern 15 is formed on an underlying layer 13 disposed on a substrate 11 by performing an exposure process and a developing process. The RELACS material 17 is coated on the entire surface of photoresist pattern, and then a thermal process is performed on the resulting structure. As a result, a cross-linkages 19 are formed between the RELACS material 17 and the photoresist pattern 15 to reduce the size of the space or contact hole of photoresist pattern.

According to the method using the SAFIER material, as shown in FIG. 3, an exposure process and a developing process are performed on an underlying layer 23 formed on a substrate 21, thereby obtaining a photoresist pattern 25. Then, the SAFIER material 27 is coated on the entire surface of the photoresist pattern, and a thermal process is performed on the resulting structure. As a result, the photoresist material is contracted 29 to reduce a size of the space or contact hole of photoresist pattern.

Although the RELACS or the SAFIER material can reduce the size of a contact hole of a photoresist pattern regardless of the duty ratio, the processes employing the RELACS and SAFIER materials are more costly and more complicated than the RFP process since the material used in the RELACS or the SAFIER is expensive and the method using the RELACS or the SAFIER material further comprises a coating process, a thermal process and a developing process.

Applicants have developed a novel method for forming a fine pattern which may overcome the above-described problems without use of expensive materials or a more complicated process.

### SUMMARY OF THE DISCLOSURE

A composition is disclosed for coating a photoresist pattern, including a water-soluble polymer which reacts with a photoresist layer to form a coating film.

A method for forming a fine photoresist pattern is disclosed which uses the above composition and a semiconductor device manufactured by using the disclosed method is also disclosed.

Additional features may become apparent to those skilled in the art from a review of the following description, taken in conjunction with the drawings, the examples, and the appended claims.

### BRIEF DESCRIPTION OF THE DRAWINGS

FIG. 1 is a cross-sectional diagram illustrating a method for forming a fine pattern according to a conventional RFP method.

FIG. 2 is a cross-sectional diagram illustrating a method for forming a fine pattern using a conventional RELACS material.

FIG. 3 is a cross-sectional diagram illustrating a method for forming a fine pattern using a conventional SAFIER material.

FIGS. 4a and 4b are cross-sectional diagrams illustrating a method for forming a fine pattern using a disclosed composition for coating a photoresist pattern;

FIG. 5 is a photograph showing a photoresist pattern obtained in comparative Example.

FIG. 6 is a photograph showing a photoresist pattern obtained in Example 3.

FIG. 7 is a photograph showing a photoresist pattern obtained in Example 4.

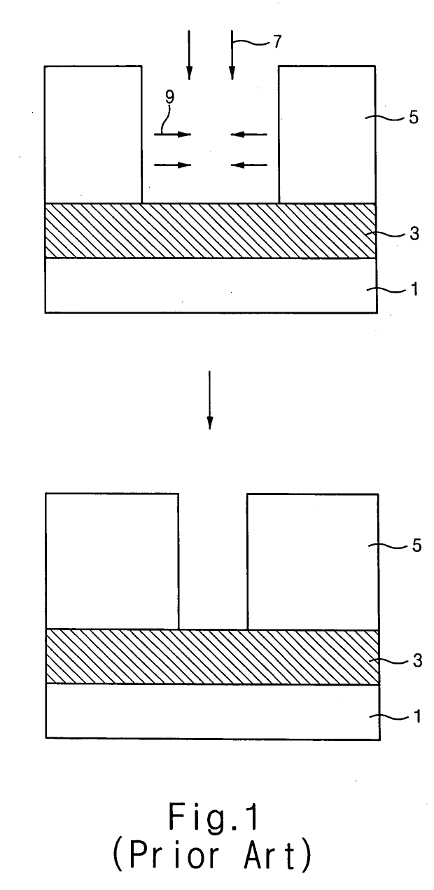

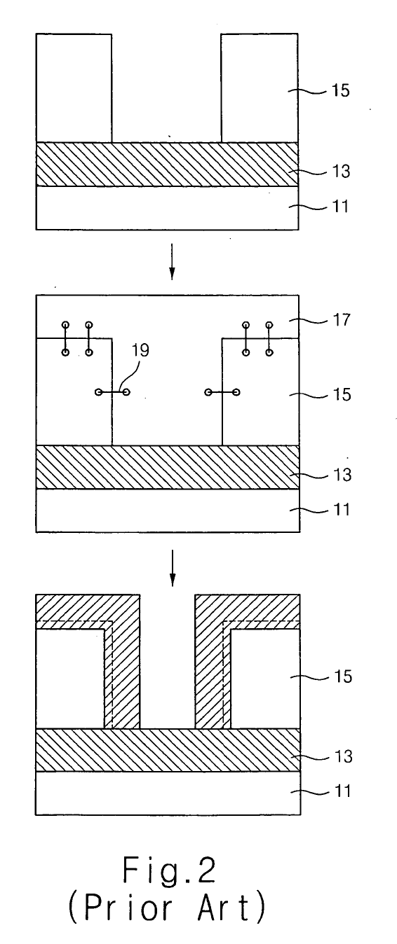

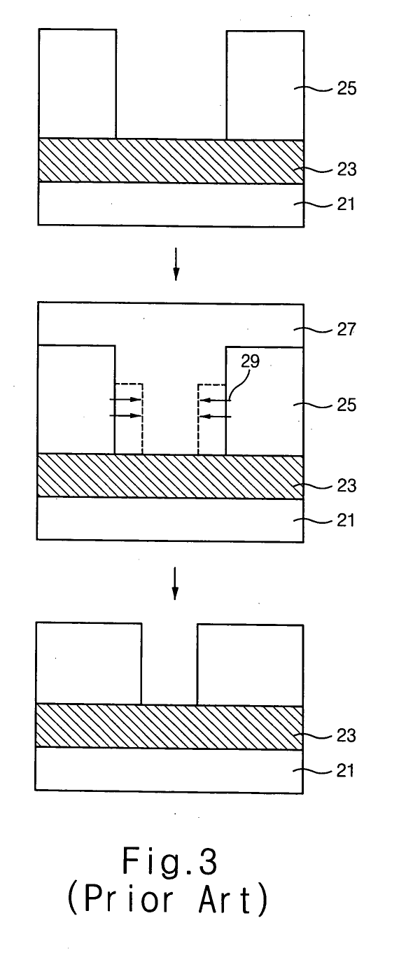

The specification, drawings and examples are intended to be illustrative, and are not intended to limit this disclosure to the specific embodiments described herein.

### DETAILED DESCRIPTION OF THE PRESENTLY PREFERRED EMBODIMENTS

Compositions for coating photoresist patterns are disclosed. The disclosed compositions can be formed a coating film along the surface of the pattern coated on a previously formed photoresist pattern.

The composition comprises water and a water-soluble polymer represented by Formula 1:

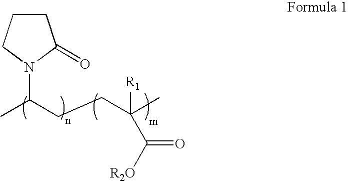

wherein R₁ and R₂ are individually selected from the group consisting of H, linear or branched C₁-C₂₀ alkyl, linear or branched C₂-C₂₀ alkyl containing an ester linkage, linear or branched C₂-C₂₀ alkyl containing a ketone linkage, linear or branched C₂-C₂₀ alkyl containing a carboxylic acid group, linear or branched C₇-C₂₀ alkyl phenyl and linear or branched C₃-C₂₀ alkyl containing a acetal linkage;

m is an integer ranging from 0 to 3000; and

n is an integer ranging from 10 to 3000.

Preferably, the R₁ and R₂ of the water-soluble polymer are individually selected from the group consisting of methyl, ethyl, propyl, butyl, octyl, octyl phenyl, nonyl, nonyl phenyl, decyl, decyl phenyl, undecyl, undecyl phenyl, dodecyl and dodecyl phenyl.

The water-soluble of Formula 1 may be poly(vinyl pyrrolidone) or poly(vinyl pyrrolidone-co-acrylic acid). The water is preferably distilled water.

Preferably, the relative ratio of water-soluble polymer of Formula 1:water in the disclosed composition is in the range of 0.001˜10 wt %:90-99.999 wt %.

A capacity for forming a coating film on a photoresist film is degraded if the compound of Formula 1 is present in an amount of less than 0.001 wt %, and the positive effects are almost the same if the compound of Formula 1 is present in an amount of more than 10 wt %.

The disclosed compositions for coating a photoresist pattern may further comprise an alcohol compound in order to improve solubility and coating characteristics.

The above-described alcohol compound is C₁-C₁₀ alkyl alcohol or C₂-C₁₀ alkoxyalkyl alcohol. Preferably, the C₁-C₁₀ alkyl alcohol is selected from the group consisting of methanol, ethanol, propanol, isopropanol, n-butanol, sec-butanol, t-butanol, 1-pentanol, 2-pentanol, 3-pentanol, 2,2-dimethyl-1-propanol and combinations thereof. The C₂-C₁₀ alkoxyalkyl alcohol is selected from the group consisting of 2-methoxyethanol, 2-(2-methoxy ethoxy)ethanol, 1-methoxy-2-propanol, 3-methoxy-1,2-propandiol and combinations thereof.

Here, the relative ratio of water-soluble polymer of Formula 1:alcohol compound:water the disclosed composition is preferably in the range of 0.01˜10 wt % 1˜10 wt %:80˜98.99 wt %.

When the alcohol compound is present in an amount of more than 10 wt %, the photoresist film is dissolved in the alcohol, so that the pattern can be deformed.

When the above-described compositions are coated on a previously formed photoresist pattern by performing a spin-coating method, hydrogen combination occurs with a photoresist layer to form a uniform a coating film. As a result, a size of space or contact hole of photoresist pattern can be reduced.

In order to achieve the above-described objects, the compound of Formula 1 should have the following performance characteristics:

(1) no damage to the photoresist pattern while coating the disclosed composition;

(2) to have excellent adhesion property so that a composition film may be thinly coated on a surface of the photoresist pattern and a exposed surface of bottom layer of a photoresist pattern when the disclosed composition is coated;

(3) to have same or better etching resistance than that of existing photoresist;

(4) not to foam on the surface of the coating film when the disclosed composition is coated; and

(5) to form a vertical pattern profile after coating composition.

A mixture solution comprising water and the compound of Formula 1 or the mixture solution further comprising an alcohol compound is filtered through a 0.2 μm filter, thereby obtaining a composition for coating a photoresist pattern. The disclosed composition can be applied to all existing processes for forming a photoresist pattern.

Additionally, a method for forming a photoresist pattern comprises:

(a) forming a photoresist film on an underlying layer of a semiconductor substrate;

(b) exposing the photoresist film to light;

(c) developing the resulting structure to obtain a desired photoresist pattern; and

(d) coating the disclosed composition for coating a photoresist pattern on the photoresist pattern.

Preferably, the method may further comprise a baking step the photoresist film either before or after the exposing step (b).

Also, there is provided a semiconductor device manufactured by the method for forming a photoresist pattern using the disclosed composition.

Hereinafter, the present disclosure will be described in detail with reference to the accompanying drawings.

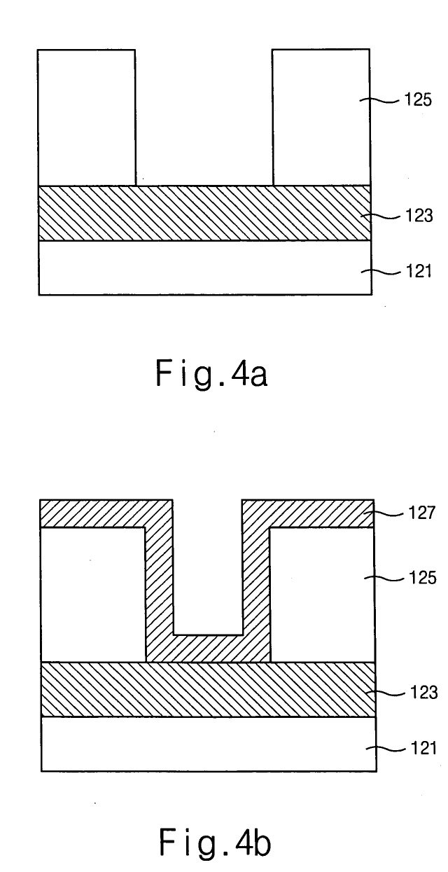

As shown in FIG. 4a, an underlying layer 123 and a photoresist layer (not shown) are sequentially formed on a semiconductor substrate 121, and then an exposure process and a developing process are performed to obtain a photoresist pattern 125.

Here, a soft baking process is performed before the exposure process, and the post baking process is performed after the exposure process. The baking process is preferably performed at a temperature ranging from about 70° C. to about 200° C.

The exposure process is performed using the source of light selected from the group consisting of KrF (248 nm), ArF (193 nm), VUV (157 nm), EUV (13 nm), E-beam, X-ray and ion beam, and the exposure process is performed at an exposure energy ranging from about 0.1 mJ/cm² to about 100 mJ/cm².

The development process is performed using an alkali developing solution such as TMAH aqueous solution in an amount ranging from 0.01 wt % to about 5 wt %.

Then, the disclosed composition for coating a photoresist pattern is spin-coated on the photoresist pattern 125 of FIG. 4a, and a layer of the composition for coating a photoresist pattern is formed as shown in FIG. 4b. As a result, a size of a space or contact hole of photoresist pattern can be reduced.

The disclosed compositions will be described in detail by referring to examples below, which are not intended to be limiting of this disclosure.

I. Preparation of Composition for Coating a Photoresist Pattern

### Example 1

To distilled water (100 g) was added poly(vinyl pyrrolidone) having an average molecular weight of 130,000 (0.5 g)(Aldrich No. 856568). The resulting mixture was stirred for 60 minutes, and then filtered through a 0.2 μm filter, thereby obtaining a disclosed composition for coating a photoresist pattern.

### Example 2

To distilled water (100 g) was added poly(vinyl pyrrolidone-co-acrylic acid) having an average molecular weight of 96,000 (0.5 g). The resulting mixture was stirred for 60 minutes, and then filtered through a 0.2 μm filter, thereby obtaining a disclosed composition for coating a photoresist pattern.

II. Formation of a Fine Pattern

### Comparative Example

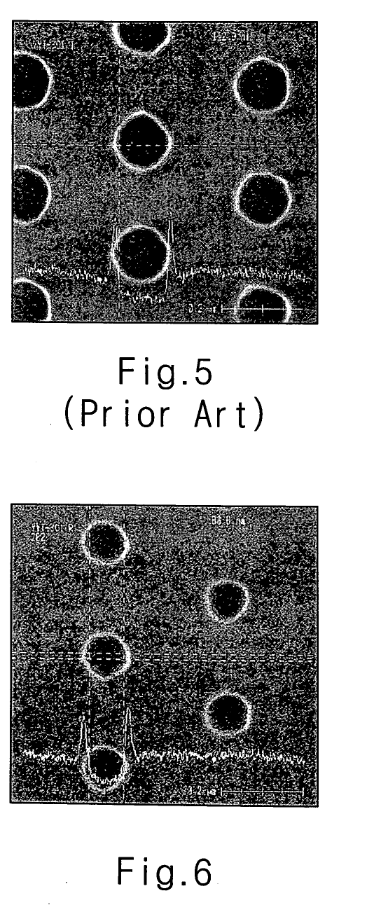

An underlying layer was formed on a silicon wafer treated with HMDS, and a methacrylate type photoresist (“TarF-7a-39” produced by TOK Co.) was spin-coated thereon to form a photoresist film at a thickness of 3,500 Å. Then, the photoresist film was soft-baked at about 130° C. for about 90 seconds. After baking, the photoresist film was exposed to light using an ArF laser exposer, and post-baked at about 130° C. for about 90 seconds. When the post-baking was completed, it was developed in 2.38 wt % TMAH solution for about 30 seconds, to obtain 110 nm contact hole pattern (see FIG. 5).

### Example 3

10 ml of the disclosed composition obtained from Example 1 was spin-coated on the 110 mn contact hole pattern obtained from Comparative Example, thereby obtaining a reduced 84 nm contact hole pattern (see FIG. 6).

### Example 4

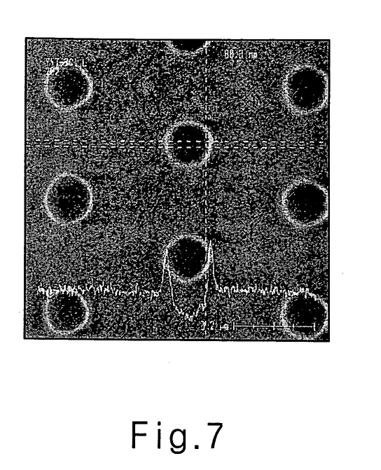

10 ml of the disclosed composition obtained from Example 2 was spin-coated on the 110 nm contact hole pattern obtained from Comparative Example, thereby obtaining a reduced 80 nm contact hole pattern (see FIG. 7).

As described above, the size of a space or contact hole of photoresist pattern can be effectively reduced when the disclosed composition for forming a photoresist pattern is coated on a previously formed photoresist pattern to obtain a composition film. As a result, the disclosed composition for coating a photoresist pattern and a method for forming a fine pattern using the same can be usefully applied to all semiconductor processes for obtaining a fine contact hole.

What is claimed is:

1. A composition for coating photoresist pattern comprising water and a water-soluble polymer represented by Formula 1: 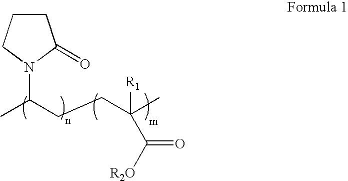
wherein R₁ and R₂ are individually selected from the group consisting of H, linear or branched C₁-C₂₀ alkyl, linear or branched C₂-C₂₀ alkyl containing an ester linkage, linear or branched C₂-C₂₀ alkyl containing a ketone linkage, linear or branched C₂-C₂₀ alkyl containing a carboxylic acid group, linear or branched C₇-C₂₀ alkyl phenyl and linear or branched C₃-C₂₀ alkyl containing a acetal linkage;
m is an integer ranging from 0 to 3000; and
n is an integer ranging from 10 to 3000.

2. The composition according to claim 1, wherein the R₁ and R₂ of the water-soluble polymer are individually selected from the group consisting of methyl, ethyl, propyl, butyl, octyl, octyl phenyl, nonyl, nonyl phenyl, decyl, decyl phenyl, undecyl, undecyl phenyl, dodecyl and dodecyl phenyl.

3. The composition according to claim 1, wherein the water-soluble polymer of Formula 1 is poly(vinyl pyrrolidone) or poly(vinyl pyrrolidone-co-acrylic acid).

4. The composition according to claim 1, wherein a ratio of water-soluble polymer of Formula 1:water is in a range of 0.001˜10 wt %:90˜99.999 wt %.

5. The composition according to claim 1, further comprising an alcohol compound.

6. The composition according to claim 5, wherein the alcohol compound is C₁-C₁₀ alkyl alcohol or C₂-C₁₀ alkoxyalkyl alcohol.

7. The composition according to claim 6, wherein the C₁-C₁₀ alkyl alcohol is selected from the group consisting of methanol, ethanol, propanol, isopropanol, n-butanol, sec-butanol, t-butanol, 1-pentanol, 2-pentanol, 3-pentanol, 2,2-dimethyl-1-propanol and combinations thereof.

8. The composition according to claim 6, wherein the C₂-C₁₀ alkoxyalkyl alcohol is selected from the group consisting of 2-methoxyethanol, 2-(2-methoxy ethoxy)ethanol, 1-methoxy-2-propanol, 3-methoxy-1,2-propandiol and combinations thereof.

9. The composition according to claim 5, wherein a ratio of water-soluble polymer of Formula 1:alcohol compound:water is in a range of 0.01˜10 wt %:1˜10 wt %:80˜98.99 wt %.

10. A method for forming a photoresist pattern comprising:
(a) forming a photoresist film on an underlying layer of a semiconductor substrate;
(b) exposing the photoresist film to light;
(c) developing the resulting structure to obtain a desired photoresist pattern; and
(d) coating the composition for coating a photoresist pattern of claim 1 on the photoresist pattern.

11. The method according to claim 10, wherein the light source of step (b) is selected from the group consisting of KrF (248 nm), ArF (193 nm), VUV (157 nm), EUV (13 nm), E-beam, X-ray and ion beam.

12. The method according to claim 10, further comprising a baking the photoresist film either before or after the exposing of step (b).

13. A method for forming a photoresist pattern comprising:
(a) forming a photoresist film on an underlying layer of a semiconductor substrate;
(b) exposing the photoresist film to light;
(c) developing the resulting structure to obtain a desired photoresist pattern; and
(d) coating the composition for coating a photoresist pattern of claim 5 on the photoresist pattern.

14. A semiconductor device manufactured by the method of claim 10.

15. A semiconductor device manufactured by the method of claim 11.

16. A semiconductor device manufactured by the method of claim 12.

17. A semiconductor device manufactured by the method of claim 13.
